(19) United States
(12) Patent Application Publication
(10) Pub. No.: US 2007/0108583 A1
(43) Pub. Date: May 17, 2007

(54) INTEGRATED CIRCUIT PACKAGE-ON-PACKAGE STACKING SYSTEM

(75) Inventors: Il Kwon Shim, Singapore (SG); Byung Joon Han, Singapore (SG); Seng Guan Chow, Singapore (SG)

Correspondence Address: ISHIMARU & ZAHRT LLP, 333 W. EL CAMINO REAL, SUITE 330, SUNNYVALE, CA, 94087, US

(73) Assignee: STATS CHIPPAC LTD., Singapore (SG)

(21) Appl. No.: 11/458,065

(22) Filed: Jul. 17, 2006

Related U.S. Application Data
(60) Provisional application No. 60/595,822, filed on Aug. 8, 2005.

(51) Int. Cl. H01L 23/12

(52) U.S. Cl. 257/686; 257/700

(57) ABSTRACT

An integrated circuit package-on-package stacking system is provided including providing a first integrated circuit package, mounting a metalized interposer substrate over the first integrated circuit package and attaching a second integrated circuit package on the metalized interposer substrate.

### CROSS-REFERENCE TO RELATED APPLICATION

This application claims the benefit of U.S. Provisional Patent Application Ser. No. 60/595,822 filed Aug. 8, 2005, and the subject matter thereof is hereby incorporated herein by reference thereto.

### TECHNICAL FIELD

The present invention relates generally to integrated circuit packaging systems, and more particularly to a system for package-on-package stacking systems

### BACKGROUND ART

The dimensions of many different types of state of the art electronic devices are ever decreasing. To reduce the dimensions of electronic devices, the structures by which the microprocessors, memory devices, other semiconductor devices, and other electronic components of these devices are packaged and assembled with circuit boards must become more compact.

One approach to reducing the sizes of assemblies of semiconductor devices and circuit boards has been to minimize the profiles of the semiconductor devices and other electronic components upon carrier substrates (e.g., circuit boards) so as to reduce the distances the semiconductor devices protrude from the carrier substrates. Various types of packaging technologies have been developed to facilitate orientation of semiconductor devices upon carrier substrates in this manner.

Some semiconductor device packages are configured to be oriented substantially parallel to a plane of a carrier substrate, such as a circuit board. Conventionally, semiconductor device packages included several layers stacked one on top of another (e.g., a bottom layer of encapsulant material, a die-attach paddle of a lead frame, a semiconductor die, and a top layer of encapsulant material). In addition, the leads or pins of conventional semiconductor device packages, which electrically connect such packages to carrier substrates, as well as provide support for the packages, are sometimes configured to space the semiconductor device packages apart from a carrier substrate. As a result, the overall thicknesses of these semiconductor device packages and the distances the packages protrude from carrier substrates are larger than is often desired for use in state of the art electronic devices.

“Flip-chip” technology, or controlled collapse chip connection (C-4), is another example of an assembly and packaging technology that results in a semiconductor device being oriented substantially parallel to a carrier substrate, such as a circuit board. In flip-chip technology, the bond pads or contact pads of a semiconductor device are arranged in an array over a major surface of the semiconductor device. Flip-chip techniques are applicable to both bare and packaged semiconductor devices. A packaged flip-chip type semiconductor device, which typically has a ball grid array connection pattern, typically includes a semiconductor die and a substrate, which is typically termed an “interposer.” The interposer may be disposed over either the back side of the semiconductor die or the front (active) surface thereof

When the interposer is positioned adjacent the back side of the semiconductor die, the bond pads of the semiconductor die are typically electrically connected by way of wire bonds or other intermediate conductive elements to corresponding contact areas on a top side of the interposer. These contact areas communicate with corresponding bumped contact pads on the back side of the interposer. This type of flip-chip assembly is positioned adjacent a carrier substrate with the back side of the interposer facing the carrier substrate.

If the interposer is positioned adjacent the active surface of the semiconductor die, the bond pads of the semiconductor die may be electrically connected to corresponding contact areas on an opposite, top surface of the interposer by way of intermediate conductive elements that extend through one or more holes formed in the interposer. Again, the contact areas communicate with corresponding contact pads on the interposer. In this type of flip-chip semiconductor device assembly, however, the contact pads are also typically located on the top surface of the interposer. Accordingly, this type of flip-chip assembly is positioned adjacent a carrier substrate by orienting the interposer with the top surface facing the carrier substrate.

In each of the foregoing types of flip-chip semiconductor devices, the contact pads of the interposer are disposed in an array that has a footprint that mirrors an arrangement of corresponding terminals formed on a carrier substrate. Each of the bond (on bare flip-chip semiconductor dice) or contact (on flip-chip packages) pads and its corresponding terminal may be electrically connected to one another by way of a conductive structure, such as a solder ball, that also spaces the interposer some distance away from the carrier substrate.

The space between the interposer and the carrier substrate may be left open or filled with a so-called “underfill” dielectric material that provides additional electrical insulation between the semiconductor device and the carrier substrate. In addition, each of the foregoing types of flip-chip type semiconductor devices may include an encapsulant material covering portions or substantially all of the interposer and/or the semiconductor die.

The thicknesses of conventional flip-chip type packages having ball grid array connection patterns are defined by the combined thicknesses of the semiconductor die, the interposer, and the conductive structures (e.g., solder balls) that protrude above the interposer or the semiconductor die. As with the flat packages, conventional flip-chip type packages are often undesirably thick for use in small, thin, state of the art electronic devices.

Thinner, or low-profile, flip-chip type packages have been developed which include recesses that are configured to at least partially receive semiconductor devices. While interposers that include recesses for partially receiving semiconductor devices facilitate the fabrication of thinner flip-chip type packages, the semiconductor dice of these packages, as well as intermediate conductive elements that protrude beyond the outer surfaces of either the semiconductor dice or the interposers, undesirably add to the thicknesses and size of these packages.

Thus, a need still remains for an integrated circuit package-on-package stacking system. In view of the commercial trends to shrink commodity electronic devices, it is increasingly critical that answers be found to these problems. Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package-on-package stacking system comprising providing a first integrated circuit package, mounting a metalized interposer substrate over the first integrated circuit package and attaching a second integrated circuit package on the metalized interposer substrate.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit package-on-package stacking system, in an embodiment of the present invention;

FIG. 2 is a cross-sectional view of an integrated circuit package-on-package stacking system, in an alternative embodiment of the present invention;

FIG. 3 is a cross-sectional view of an integrated circuit package-on-package stacking system, in a further alternative embodiment of the present invention;

FIG. 4 is a cross-sectional view of an integrated circuit package-on-package stacking system, in a still further alternative embodiment of the present invention;

FIG. 5 is a flow chart of an integrated circuit package-on-package stacking system for manufacturing the integrated circuit package-on-package stacking system, in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Where multiple embodiments are disclosed and described, having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the integrated circuit regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “system” means the method and the apparatus of the present invention. The term “processing” as used herein includes stamping, forging, patterning, exposure, development, etching, cleaning, and/or removal of the material or laser trimming as required in forming a described structure.

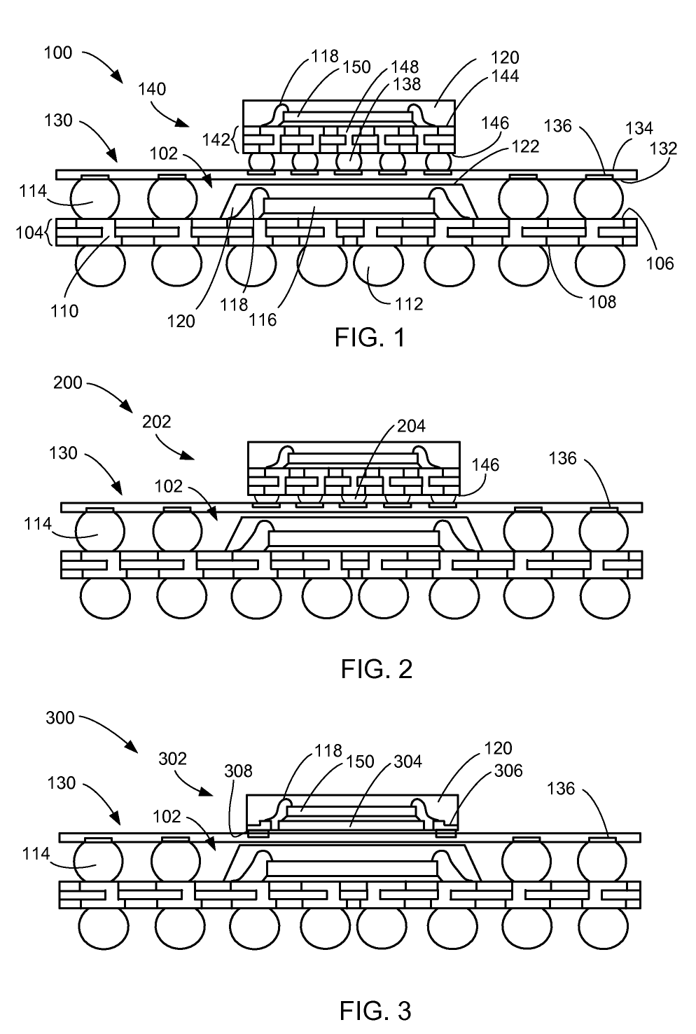

Referring now to FIG. 1, therein is shown a cross-sectional view of an integrated circuit package-on-package stacking system 100, in an embodiment of the present invention. The cross-sectional view of the integrated circuit package-on-package stacking system 100 depicts a first integrated circuit package 102 having a first substrate 104 with a substrate top 106 and a substrate bottom 108. The first substrate 104 has a through conductor 110, which serves as the attach point, on the substrate bottom 108, for electrical interconnects 112, such as solder balls, solder columns or stud bumps. The through conductor 110 is also the attach point, on the substrate top 106, for transition interconnects 114, such as solder balls, solder columns or stud bumps. A first integrated circuit 116 is mounted on the substrate top 106 and is coupled to the substrate top 106 by bond wires 118. An epoxy molding compound 120 encapsulates the first integrated circuit 116, the bond wires 118, and a portion of the substrate top 106.

A mold cap 122, on the epoxy molding compound 120, is positioned slightly below a metalized interposer substrate 130, such as a flexible tape, an organic epoxy resin, a ceramic, an FR4 printed circuit board, or low dielectric materials. The mold cap 122 may act as a stabilizer preventing collapse of the transition interconnects 114 during the reflow process. The metalized interposer substrate 130 has an interposer bottom 132 and an interposer top 134. There are contact pads 136 on both the interposer top 134 and the interposer bottom 132. The contact pads 136 on the interposer bottom 132 serve as attach points for the transition interconnects 114, while the contact pads 136 on the interposer top 134 serve as attach points for secondary interconnects 138, such as solder balls, solder columns or stud bumps.

A second integrated circuit package 140, such as a ball grid array package, is mounted on the interposer top 134 and coupled to the contact pads 136 by the secondary interconnects 138. The second integrated circuit package 140 has a second substrate 142 with a second substrate top 144 and a second substrate bottom 146. The second substrate 142 has contact vias 148 that act as a signal path to a second integrated circuit 150, which may be a wire bond IC or a flipchip IC. In this example, the second integrated circuit 150 is a wire bond IC and is coupled to the contact vias 148 by the bond wires 118. The epoxy molding compound 120 encapsulates the second integrated circuit 150, the bond wires 118, and the second substrate top 144.

The second integrated circuit package 140 may be a smaller size than the first integrated circuit package 102. The metalized interposer substrate 130 provides a redistribution layer for bridging electrical connections between the first integrated circuit package 102 and the second integrated circuit package 140. The metalized interposer substrate 130 may provide a flexible ball pitch for the second integrated circuit package 140, thus allowing the second integrated circuit package 140 to be much smaller than the first integrated circuit package 102.

Referring now to FIG. 2, therein is shown a cross-sectional view of an integrated circuit package-on-package stacking system 200, in an alternative embodiment of the present invention. The cross-sectional view of the integrated circuit package-on-package stacking system 200 depicts the first integrated circuit package 102 coupled to the metalized interposer substrate 130 by the transition interconnects 114. A second integrated circuit package 202, such as a land grid array package, is mounted on the metalized interposer substrate 130. The second integrated circuit package 202 is attached to the contact pads 136 by a land 204, such as a gold plated copper region, on the second substrate bottom 146. The use of the land 204 interface helps reduce the over all height of the integrated circuit package-on-package stacking system 200.

Referring now to FIG. 3, therein is shown a cross-sectional view of an integrated circuit package-on-package stacking system 300, in a further alternative embodiment of the present invention. The cross-sectional view of the integrated circuit package-on-package stacking system 300 depicts the first integrated circuit package 102 coupled to the metalized interposer substrate 130 by the transition interconnects 114. A second integrated circuit package 302, such as a leadless package or a quad flat no-lead package (QFN), is mounted on the metalized interposer substrate 130.

The second integrated circuit package 302 has a die paddle 304, which may be optional, and the second integrated circuit 150 mounted thereon. For illustrative purposes the second integrated circuit package 302 is shown as a wire bond IC, though it is understood that it may also be a flipchip type of integrated circuit. The second integrated circuit 150 is coupled to an interface contact 306 by the bond wires 118. The second integrated circuit package 302 is electrically connected to the metalized interposer substrate 130 by a solder paste 308 between the interface contact 306 and the contact pads 136. The epoxy molding compound 120 encapsulates the second integrated circuit 150, the bond wires 118, the die paddle 304, and the interface contact 306.

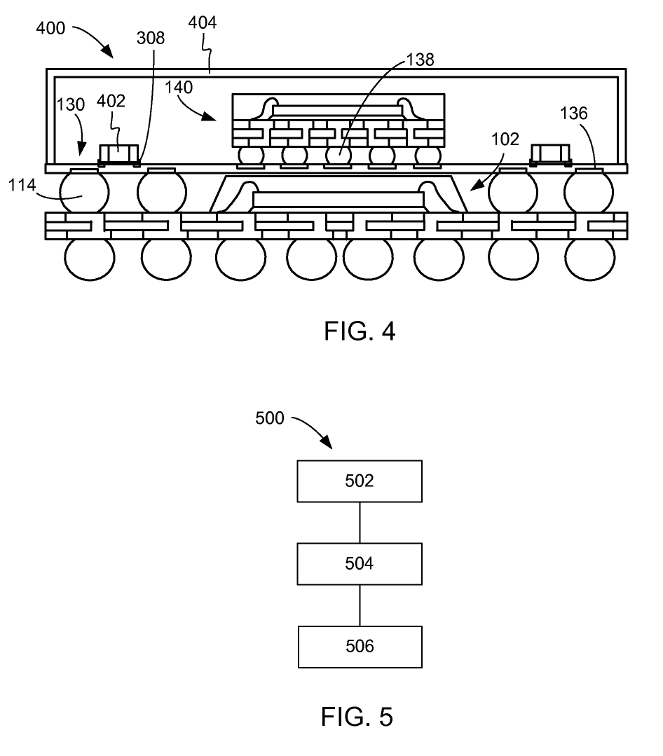

Referring now to FIG. 4, therein is shown a cross-sectional view of an integrated circuit package-on-package stacking system 400, in a still further alternative embodiment of the present invention. The cross-sectional view of the integrated circuit package-on-package stacking system 400 depicts the first integrated circuit package 102 coupled to the metalized interposer substrate 130 by the transition interconnects 114. The second integrated circuit package 140, such as a ball grid array package, is mounted on the contact pads 136 by the secondary interconnects 138.

A discrete component 402, such as an active or a passive component, may be attached to the contact pads 136 by the solder paste 308. The addition of the discrete component 402 adds flexibility to the integrated circuit package-on-package stacking system 400. An electromagnetic shield 404 or a heat sink (not shown) may optionally be added to the integrated circuit package-on-package stacking system 400 for an additional level of flexibility.

Referring now to FIG. 5, therein is shown a flow chart of an integrated circuit package-on-package stacking system 500 for the manufacture of the integrated circuit package-on-package stacking system in an embodiment of the present invention. The system 500 includes providing a first integrated circuit package in a block 502; mounting a metalized interposer substrate over the first integrated circuit package in a block 504; and attaching a second integrated circuit package on the metalized interposer substrate in a block 506.

In greater detail, a system to provide an integrated circuit package-on-package stacking system, in an embodiment of the present invention, is performed as follows:
1. Providing a first integrated circuit package having a through conductor. (FIG. 1)
2. Mounting a metalized interposer substrate over the first integrated circuit package, in which the metalized interposer substrate provides a redistribution layer. (FIG. 1) and
3. Attaching a second integrated circuit package on the metalized interposer substrate, in which providing a ball pitch for the second integrated circuit package requires less space than for the first integrated circuit package. (FIG. 1)

It has been unexpectedly discovered that attaching a small package on the metalized interposer substrate reduces the thermal expansion mismatch around the peripheral balls of the bottom package, thus enhancing the solder joint reliability.

It has been discovered that the present invention thus has numerous aspects.

A principle aspect that has been unexpectedly discovered is that the present invention provides a way to reduce manufacturing costs while increasing the solder joint reliability of the package-on-package system.

Another aspect is the several different types of package may be applied in the second package location. The flexibility of the metalized interposer substrate provides a quick and reliable way to combine functions in a package-on-package stack.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit package-on-package stacking system, of the present invention furnishes important and heretofore unknown and unavailable solutions, capabilities, and functional aspects for producing stacked package designs. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package-on-package stacking system comprising:
providing a first integrated circuit package;
mounting a metalized interposer substrate over the first integrated circuit package; and
attaching a second integrated circuit package on the metalized interposer substrate.

2. The system as claimed in claim 1 further comprising providing a transition interconnect on the first integrated circuit package.

3. The system as claimed in claim 1 further comprising:
providing a contact pad on the metalized interposer substrate; and
coupling a discrete component to the contact pad.

4. The system as claimed in claim 1 wherein attaching the second integrated circuit package includes providing the second integrated circuit package in which the second integrated circuit package being smaller than the first integrated circuit package.

5. The system as claimed in claim 1 further comprising providing an electromagnetic shield over the second integrated circuit package, a discrete component, or a combination thereof.

6. An integrated circuit package-on-package stacking system comprising:
providing a first integrated circuit package having a through conductor;
mounting a metalized interposer substrate over the first integrated circuit package, in which the metalized interposer substrate provides a redistribution layer; and
attaching a second integrated circuit package on the metalized interposer substrate, in which providing a ball pitch for the second integrated circuit package requires less space than for the first integrated circuit package.

7. The system as claimed in claim 6 further comprising providing a transition interconnect on the first integrated circuit package, in which providing the transition interconnect includes providing a solder ball.

8. The system as claimed in claim 6 further comprising:
providing a contact pad on the metalized interposer substrate, in which providing a contact pad includes a contact pad on the interposer top and on the interposer bottom; and
coupling a discrete component to the contact pad, in which coupling the discrete component may provide an active component or a passive component.

9. The system as claimed in claim 6 wherein attaching the second integrated circuit package includes providing the second integrated circuit package in which the second integrated circuit package being smaller than the first integrated circuit package, with the second integrated circuit package including a land grid array, a ball grid array, or a leadless package.

10. The system as claimed in claim 6 further comprising providing an electromagnetic shield over the second integrated circuit package, a discrete component, or a combination thereof, in which providing the electromagnetic shield includes mounting the electromagnetic shield on the metalized interposer substrate.

11. An integrated circuit package-on-package stacking system comprising:
a first integrated circuit package;
a metalized interposer substrate over the first integrated circuit package; and
a second integrated circuit package on the metalized interposer substrate.

12. The system as claimed in claim 11 further comprising a transition interconnect on the first integrated circuit package.

13. The system as claimed in claim 11 further comprising:
a contact pad on the metalized interposer substrate; and
a discrete component coupled to the contact pad.

14. The system as claimed in claim 11 wherein the second integrated circuit package on the metalized interposer substrate, includes the second integrated circuit package is smaller than the first integrated circuit package.

15. The system as claimed in claim 11 further comprising an electromagnetic shield over the second integrated circuit package, a discrete component, or a combination thereof.

16. The system as claimed in claim 11 further comprising:
a through conductor in the first integrated circuit package;
a redistribution layer; and
a ball pitch for the second integrated circuit package requires less space than for the first integrated circuit package.

17. The system as claimed in claim 16 further comprising a transition interconnect on the first integrated circuit package, in which the transition interconnect includes a solder ball.

18. The system as claimed in claim 16 further comprising:
a contact pad on the metalized interposer substrate, includes a contact pad on the interposer top and on the interposer bottom; and
a discrete component coupled to the contact pad, in which the discrete component may provide an active component or a passive component.

19. The system as claimed in claim 16 wherein the second integrated circuit package attached includes the second integrated circuit package is smaller than the first integrated circuit package, with the second integrated circuit package includes a land grid array, a ball grid array, or a leadless package.

20. The system as claimed in claim 16 further comprising an electromagnetic shield over the second integrated circuit package, a discrete component, or a combination thereof, in which the electromagnetic shield is mounted on the metalized interposer substrate.
